(19) United States
(12) Patent Application Publication
(10) Pub. No.: US 2009/0167389 A1
(43) Pub. Date: Jul. 2, 2009

(54) Voltage-Controlled Oscillator

(75) Inventor: Ricardo dos Santos REIS, Turcifal (PT)

Correspondence Address: STERNE, KESSLER, GOLDSTEIN & FOX P.L.L.C., 1100 NEW YORK AVENUE, N.W., WASHINGTON, DC, 20005, US

(73) Assignee: ChipIdea Microelectronica S.A., Porto Salvo (PT)

(21) Appl. No.: 11/968,112

(22) Filed: Dec. 31, 2007

(51) Int. Cl. H03L 7/08

(52) U.S. Cl. 327/159; 331/17

(57) ABSTRACT

The present invention discloses a calibration circuit for a voltage-controlled oscillator (10a-10c) and also a method for calibrating the voltage-controlled oscillator. The apparatus comprises a first counter (210) for counting the number of cycles of a reference signal (Fclk) and a second counter (220) for counting the number of cycles of a feedback signal (Fin) produced by the voltage-controlled oscillator (10a-10c). The second counter (220) is further adapted to produce a difference value (OUTVAL) representative of the difference between the phase of the reference signal (Fclk) and the phase of the feedback signal (Fin). A memory (240) has a plurality of memory locations storing the difference values (OUTVAL) and capacitor selections. The apparatus further comprises a capacitor bank (90) selectable by the capacitor selections in the memory (240) and connected to the voltage-controlled oscillator (10a-10c). The calibration circuit is used in a phase-locked loop for the voltage-controlled oscillator (10a-10c).

### TECHNICAL FIELD OF THE INVENTION

This invention relates to a voltage-controlled oscillator (VCO).

### BACKGROUND OF THE INVENTION

A voltage-controlled oscillator (or VCO) is an electronic oscillator which is designed to be controlled in oscillation frequency by a voltage input. The output oscillation frequency is varied by the application of a DC input voltage.

One application of the VCO is as a local oscillator in radio-frequency (RF) applications to produce an adjustable-carrier or heterodyning frequency. The local oscillator has an adjustable frequency that enables a transceiver to communicate over a chosen channel. The transceiver usually includes a phase-locked loop to ensure that the phase of the VCO is kept aligned with the phase of a reference frequency.

### SUMMARY OF THE INVENTION

The invention comprises a calibration circuit for a voltage-controlled oscillator. The calibration circuit comprises a first counter for counting the number of cycles of a reference signal and a second counter for counting the number of cycles of a feedback signal produced by the voltage-controlled oscillator. The second counter is adapted to produce a difference value representative of the difference between the frequency of the reference signal and the frequency of the feedback signal. A memory comprising a plurality of memory locations stores a plurality of the difference values and associated capacitor selections. The associated capacitor selections are used to select capacitors in a capacitor bank in which the capacitor bank is connected to an input of the voltage-controlled oscillator. The presence of the memory locations with associated capacitor selections allows the fast and efficient control of the voltage-controlled oscillator since on initialization the values of the capacitor selections are stored in the memory locations.

In one aspect of the invention, a sweeper is used for selecting possible values of the capacitor selections and thus sweeping through possible combinations during the initialization of the voltage controlled oscillator.

The invention also includes a method for the calibration of a voltage-controlled oscillator which comprises the selecting of a capacitor selection in a capacitance bank connected to an input of the voltage-controlled oscillator, measuring the difference frequency between a frequency of a reference signal and a frequency of a feedback signal produced by the voltage-controlled oscillator and then storing a value representative of the difference frequency in a memory together with the capacitor selection.

This method is repeated with a new capacitor selection and then measuring a changed difference frequency and storing a further value representative of the changed difference frequency in the memory together with the new capacitor selection. The method is repeated until all of the possible capacitor selections have been selected.

The method is used in a phase-locked loop for aligning an output phase of a voltage-controlled oscillator with the input phase of the voltage-controlled oscillator. The phase-locked loop (or PLL) has a phase/frequency detector for detecting changes in the output phase of the voltage-controlled oscillator compared with the input phase of the voltage-controlled oscillator and the selectable capacitor bank attached to an input of the voltage-controlled oscillator. A look-up table is used for storing a plurality of values representative of the difference between the output phase of the voltage-controlled oscillator and the input phase of the voltage-controlled oscillator and for storing a plurality of values of capacitor selections adapted to select capacitors in the selectable capacitor bank.

In one aspect of the invention, the phase-locked loop has a frequency detector with input integer values and fractional values from a sigma-delta divider.

Finally, the invention includes a method of adjusting the frequency of a voltage controlled oscillator in which a difference value is measured between the output phase of the voltage-controlled oscillator and the input phase of the voltage-controlled oscillator. The difference value is used to look up in a memory a capacitor selection and the capacitor selection used to change a capacitance value at a capacitor bank attached to an input of the voltage-controlled oscillator.

### BRIEF DESCRIPTION OF THE DRAWINGS

FIG. 1 illustrates a plurality of local oscillators with a phase locked loop.

FIG. 2 illustrates a calibration of the voltage controlled oscillators.

FIG. 3 illustrates an example of a voltage controlled oscillator.

### DETAILED DESCRIPTION OF THE PREFERRED EMBODIMENTS OF THE INVENTION

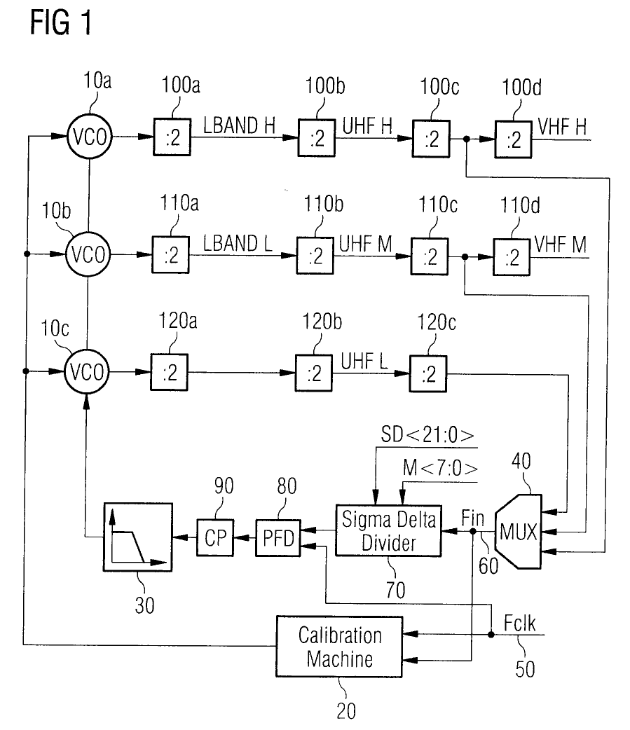

FIG. 1 illustrates an example of voltage-controlled oscillators (VCO) used in a transceiver—in this case a TV tuner—with a phase controlled loop. FIG. 1 shows a first VCO 10a, a second VCO 10b and a third VCO 10c. In the example the first VCO 10a has an output oscillation frequency between 3120 MHz and 3840 MHz. The second VCO 10b has an output oscillation frequency between 2460 MHz and 3120 MHz. The third VCO 10c has an output oscillation frequency between 1880 MHz and 2460 MHz. It will be appreciated that the three VCOs 10a-10b illustrated in FIG. 1 are merely illustrative and that further or fewer VCOs may be incorporated and that the output oscillation frequency chosen depends on the application and is not limited to the above values.

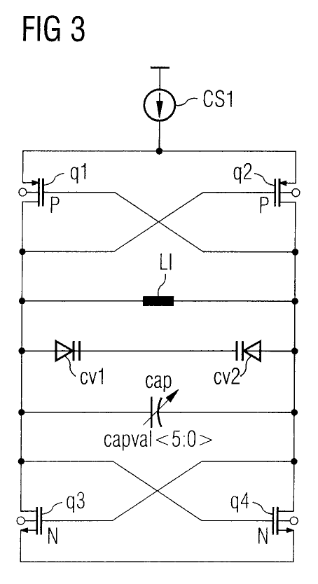

FIG. 3 shows a circuit diagram of any one of the VCOs 10a, 10b or 10c. The VCO comprises a constant current source CS1 which is connected to a first p-type transistor q1 and a second p-type transistor q2 and also to a first n-type transistor q3 and a second n-type transistor q4. The gate of the first p-type transistor q1 is connected to the drain of the second p-type transistor q2, the gate of the first n-type transistor q3 and the drain of the second n-type transistor q4. Similarly the gate of the second p-type transistor q2 is connected to the drain of the first p-type transistor q1, the drain of the first n-type transistor q3 and the gate of the second n-type transistor q4. A tank circuit comprising an inductor L1 as well as two varactors cv1 and cv2 are coupled across the first p-type transistor q1 and the second p-type transistor q2 as well as the first n-type transistor q3 and the second n-type transistor q4. A bank of capacitors—here shown a variable capacitor cap—is also coupled across the first p-type transistor q1 and the second p-type transistor q2 as well as the first n-type transistor q3 and the second n-type transistor q4. The frequency of the VCO can be adjusted by changing the values of the circuit components.

The first VCO 10a, the second VCO 10b and the third VCO 10c are connected to a calibration machine 20 which function will be described later and to an integrator 30. The calibration machine 20 has as reference input a reference signal Fclk at 50 and a feedback signal Fin from a multiplexer 40. The multiplexer 40 has as its inputs the feedback signals from the first VCO 10a, the second VCO 10b and the third VCO 10c (divided by 8 as will be described later) and selects one of the feedback signals for passage to the calibration machine 20 and a sigma delta divider 70.

The phase-locked loop also includes the sigma delta (fractional) divider 70 having as inputs values SD and M and the feedback signal Fin from the multiplexer 40 at a multiplexer output 60. The output of the sigma delta divider 70 is passed to a phase frequency detector 80 and thence to a charge pump 90. The output of the charge pump 90 is passed to the integrator 30 where it control the output frequencies of the first VCO 10a, the second VCO 10b or the third VCO 10c.

The output of the first VCO 10a is passed to a first frequency divider 100a which produces at its output a signal with a frequency in the (IEEE) LBAND and to a second frequency divider 100b. and is also passed to a third frequency divider 100c. The output of the second frequency divider 100b has an output frequency in the UHF band The output of the third frequency divider 110c is passed to the multiplexer 40 and is also passed to a fourth frequency divider 100d. The fourth frequency divider 100d has an output frequency in the VHF band.

Similarly the output of the second VCO 10b is passed to a fifth frequency divider 110a which produces at its output a signal with a frequency in the (IEEE) LBAND and to a sixth frequency divider 110b. The output of the sixth frequency divider 110b has an output frequency in the UHF band and is also passed to a seventh frequency divider 110c. The output of the seventh frequency divider 110c is passed to the multiplexer 40 and is also passed to an eighth frequency divider 110d. The eighth frequency divider 110d has an output frequency in the VHF band.

Finally the output of the third VCO 10c is passed to a ninth frequency divider 120a from which the output of the ninth frequency divider 120a is passed to a tenth frequency divider 120b. The tenth frequency divider 120b produces an output signal with a frequency in the UHF band. The output of the tenth frequency divider 120b is also passed to an eleventh frequency divider 120c which passes its output to the multiplexer 40.

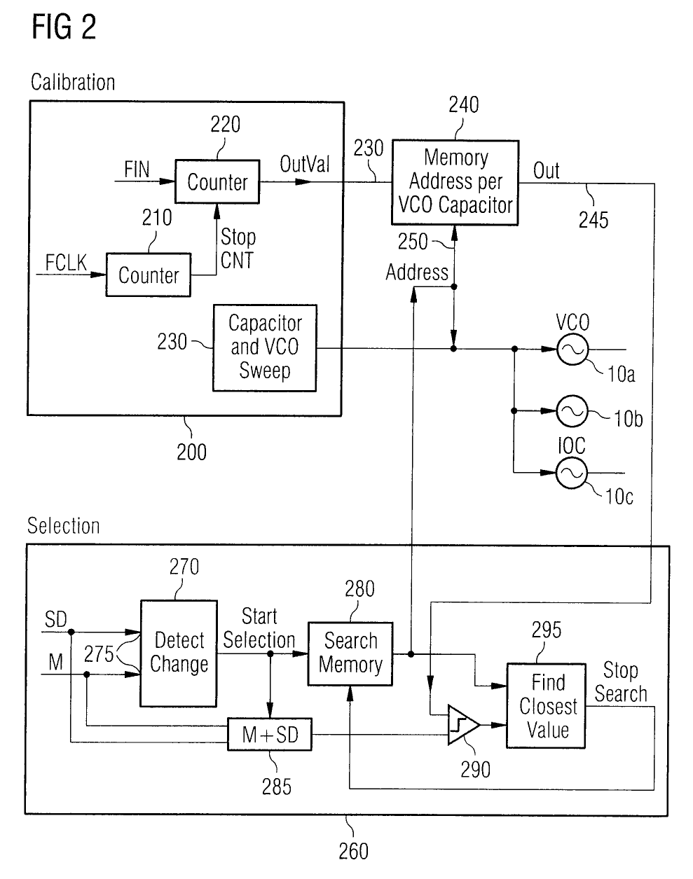

The calibration of one or all of the VCOs 10a-10c will now be described with respect to FIG. 2. FIG. 2 shows a calibration network 200 with a first counter 210 which counts the number of cycles of the reference signal Fclk and a second counter 220 which counts the number of cycles of the feedback signal Fin. The output of the second counter 210 is a value OUTVAL at 230 which is indicative of the difference in frequency between the reference signal Fclk and the feedback signal Fin. The calibration system 200 also includes a memory 240 which includes the addresses of the input capacitors for the three VCOs 10a-10c and a sweeper 230.

The calibration is carried out on initialization of the circuit by initially sweeping through all the possible values of input capacitors at each of the VCOs 10a-10c to which the sweeper 230 is connected. The selection of the possible input capacitors is carried out one at a time by using the sweeper 230 and storing the value OUTVAL for each of the different selection of the possible input capacitors in the memory 240. This calibration procedure is done as follows.

In a first step, an initial selection of the possible input capacitors is made. The capacitors attached to the inputs of the VCOs 10a-10c are arranged as a bank of capacitors which can be selected by a binary number. In the example the binary number is a six bit number. However, this is not limiting of the invention.

In a second step, the second counter 210 measures the number of cycles of the feedback frequency Fin within a fixed time period. The fixed time period is calculated by counting a fixed number of cycles of the reference signal. Since the period of the reference signal is known, the fixed time period is determined as the product of the fixed number of cycles multiplied by the period of the reference signal. On reaching the fixed number of cycles a signal STOP_CNT is sent to the second counter 210 to stop the counting of the number of cycles of the feedback signal Fin. The value OUTVAL stored in the memory is the number of clock cycles of the feedback frequence Fin counted during a fixed number of the reference cycles derived from the reference signal Fclk.

As described above, the selection of the capacitors is done in one aspect of the invention using a six bit binary number. The same six bit binary number can also be used to address the memory at which the value OUTVALUE is stored

The value OUTVAL for this selection of capacitors (given from the sweeper 230) is stored in the memory 240 in the third step at the address indicated by the selection of the capacitors. The value OUTVAL can subsequently be recovered by selecting the memory address at which it is stored. Alternatively, the memory 240 is able accept as an input a request value and then return the memory address of the memory location which has the value OUTVAL closest to the request value. The memory 240 together with associated logic is then in a position to choose the value of the capacitance that needs to be applied to the input of the one of the VCOs 10a-10c used in order to adjust the output frequency of the VCO 10a-10c (which is eight times the frequency of the feedback signal Fin because of the frequency dividers 100a-100c; 110a-110c and 120a-120c). The value of the capacitance is selected by outputting the address of the location in the memory 240 at output 250 which is then transmitted to the capacitor bank situated at the input of the VCOs 10a-10c.

The operation of a selection circuit 260 will now be described. The selection circuit 260 comprises a change detector 270 which takes at its input 275 the values M and SD from the delta sigma divider 70. The change detector 270 detects a change in the values of SD and M and initiates a memory search 280. The change detector 270 calculates from the values of SD and M a difference value which is representative of the difference between the frequency of the feedback signal Fin counted during a fixed number of Fclk cycles (i.e. a value similar to the value OUTVAL from the calibration system 200). The memory search 280 passes the difference value as a request value to the memory 240. As discussed above, the memory 240 finds the closest value stored to the difference value. From the address of the memory location of the closest value store, associated logic is able to change the values of the capacitance at the input of the VCOs 10a-10c by switching the capacitor banks (as described above) and outputs on a second output 245 the closest value stored in the memory location (and now corresponding to the new capacitance at the inputs of the VCOs 10a-10c).

The values of SD and M give origin to a difference value that is then passed to a comparator 290 where the difference value are compared with the closest value received from the second output 245 of the memory. In block 295 a check is made to see whether the difference value from SD and M is the closest to the one received from the memory 240. If this is the case then no further search of the memory 240 is required. If, however, this is not the case, then a further search of the memory is initiated in the memory search 280 to determine a better closest value. This step is repeated until the closest values have been determined.

While various embodiments of the present invention have been described above, it should be understood that they have been presented by way of example, and not limitation. It will be apparent to persons skilled in the relevant arts that various changes in form and detail can be made therein without departing from the scope of the invention. For example, in addition to using hardware (e.g., within or coupled to a Central Processing Unit (“CPU”), microprocessor, microcontroller, digital signal processor, processor core, System on Chip (“SOC”), or any other device), implementations may also be embodied in software (e.g., computer readable code, program code and/or instructions disposed in any form, such as source, object or machine language) disposed, for example, in a computer usable (e.g., readable) medium configured to store the software. Such software can enable, for example, the function, fabrication, modeling, simulation, description and/or testing of the apparatus and methods described herein. For example, this can be accomplished through the use of general programming languages (e.g., C, C++), hardware description languages (HDL) including Verilog HDL, VHDL, SystemC Register Transfer Level (RTL), and so on, or other available programs. Such software can be disposed in any known computer usable medium such as semiconductor, magnetic disk, optical disk (e.g., CD-ROM, DVD-ROM, etc.). Embodiments of the present invention may include methods of providing an apparatus described herein by providing software describing the apparatus and subsequently transmitting the software as a computer data signal over a communication network including the Internet and intranets.

It is understood that the apparatus and method embodiments described herein may be included in a semiconductor intellectual property core, (e.g., embodied in HDL) and transformed to hardware in the production of integrated circuits. Additionally, the apparatus and method embodiments described herein may be embodied as a combination of hardware and software. Thus, the present invention should not be limited by any of the above-described exemplary embodiments, but should be defined only in accordance with the following claims and their equivalence. Furthermore, it should be appreciated that the detailed description of the present invention provided herein, and not the summary and abstract sections, is intended to be used to interpret the claims. The summary and abstract sections may set forth one or more but not all exemplary embodiments of the present invention.

What is claimed is:

1. A calibration circuit for a voltage-controlled oscillator comprising:
a first counter for counting the number of cycles of a reference signal;
a second counter for counting the number of cycles of a feedback signal produced by the voltage-controlled oscillator, wherein the second counter is adapted to produce a difference value representative of the difference between the frequency of the reference signal and the frequency of the feedback signal;
a memory comprising a plurality of memory locations storing a plurality of the difference values and associated capacitor selections; and
a capacitor bank selectable by the associated capacitor selections in the memory, wherein the capacitor bank is connected to an input of the voltage-controlled oscillator.

2. The calibration circuit of claim 1, further comprising a sweeper for selecting possible values of the capacitor selections.

3. A method for the calibration of a voltage-controlled oscillator comprising:
selecting a capacitor selection in a capacitance bank connected to an input of the voltage-controlled oscillator;
measuring the difference frequency between a frequency of a reference signal and a frequency of a feedback signal produced by the voltage-controlled oscillator;
storing a value representative of the difference frequency in a memory together with the capacitor selection.

4. The method of claim 3, further comprising repeating the method with a new capacitor selection, measuring a changed difference frequency and storing a further value representative of the changed difference frequency in the memory together with the new capacitor selection.

5. The method of claim 4, further comprising repeating the method until all of the possible capacitor selections have been selected.

6. A phase-locked loop for aligning an output phase of a voltage-controlled oscillator with the input phase of the voltage-controlled oscillator comprising:
a phase/frequency detector for detecting changes in the output phase of the voltage-controlled oscillator compared with the input phase of the voltage-controlled oscillator;
a selectable capacitor bank attached to an input of the voltage-controlled oscillator
a look-up table for storing a plurality of values representative of the difference between the output phase of the voltage-controlled oscillator and the input phase of the voltage-controlled oscillator and for storing a plurality of values of capacitor selections adapted to select capacitors in the selectable capacitor bank.

7. The phase-locked loop according to claim 6, wherein the phase/frequency detector has as input integer values and fractional values from a sigma-delta divider.

8. The phase-locked loop according to claim 6, further comprising a plurality of selectable voltage-controlled oscillators with a plurality of selectable capacitor banks.

9. The phase-locked loop according to claim 6, further comprising at least one frequency divider attached to the output of a voltage-controlled oscillator.

10. A method of adjusting the frequency of a voltage controlled oscillator comprising:
measuring a difference value between the output phase of the voltage-controlled oscillator and the input phase of the voltage-controlled oscillator;
using the difference value to look up in a memory a capacitor selection;
using the capacitor selection to change a capacitance value at a capacitor bank attached to an input of the voltage-controlled oscillator.

11. The method of claim 10, further comprising
pre-storing a plurality of difference values in the memory by choosing a plurality of capacitance values at the capacitance bank and measuring the difference values between a phase of a reference signal and the output phase of the voltage-controlled oscillator.

12. The method of claim 10, further comprising
choosing a capacitor selection having a difference value closest to the measured difference value.

13. A computer program product embodied on a computer-readable medium and comprising executable instructions for the manufacture of a calibration circuit for a voltage-controlled oscillator comprising:
a first counter for counting the number of cycles of a reference signal;
a second counter for counting the number of cycles of a feedback signal produced by the voltage-controlled oscillator, wherein the second counter is adapted to produce a difference value representative of the difference between the frequency of the reference signal and the frequency of the feedback signal;
a memory comprising a plurality of memory locations storing a plurality of the difference values and associated capacitor selections; and
a capacitor bank selectable by the associated capacitor selections in the memory, wherein the capacitor bank is connected to an input of the voltage-controlled oscillator.

14. The computer program product of claim 12, wherein the executable instructions are programmed in a hardware description language selected from the group consisting of Verilog, VHDL and RTL.
